(19) United States
(12) Patent Application Publication
(10) Pub. No.: US 2017/0279464 A1
(43) Pub. Date: Sep. 28, 2017

(54) METHOD OF LDPC CODE ENCODING FOR REDUCING SIGNAL OVERHEAD AND APPARATUS THEREFOR

(71) Applicant: LG ELECTRONICS INC., Seoul (KR)

(72) Inventors: Kwangseok NOH, Seoul (KR); Dongkyu KIM, Seoul (KR); Sangrim LEE, Seoul (KR); Hojae LEE, Seoul (KR)

(73) Assignee: LG ELECTRONICS INC., Seoul (KR)

(21) Appl. No.: 15/466,355

(22) Filed: Mar. 22, 2017

Related U.S. Application Data
(60) Provisional application No. 62/311,418, filed on Mar. 22, 2016.

(51) Int. Cl. H03M 13/25; H03M 13/09; H03M 13/11

(52) U.S. Cl. CPC H03M 13/255; H03M 13/1102; H03M 13/09

(57) ABSTRACT

A method of low-density parity check (LDPC) code encoding and an apparatus therefor are disclosed. The LDPC code encoding method includes determining whether code block cyclic redundancy check (CRC) is attached to a code block based on a channel state or a required error rate. Signal overhead is reduced via selective application of the code block CRC.

### CROSS REFERENCE TO RELATED APPLICATIONS

This application claims priority to U.S. Provisional Application No. 62/311,418 filed on Mar. 22, 2016, all of which are hereby incorporated by reference in their entireties as if fully set forth herein.

### BACKGROUND OF THE INVENTION

Field of the Invention

The present invention relates to a channel coding method in a wireless communication system, and more particularly, to a method of low-density parity check (LDPC) code encoding for reducing signal overhead and an apparatus therefor.

Discussion of the Related Art

Wireless communication systems have been widely deployed in order to provide various types of communication services including voice and data services. In general, a wireless communication system is a multiple access system that can support communication with multiple users by sharing available system resources (a bandwidth, transmission power, etc.). Examples of multiple access systems include code division multiple access (CDMA), frequency division multiple access (FDMA), time division multiple access (TDMA), orthogonal frequency division multiple access (OFDMA), single carrier frequency division multiple access (SC-FDMA), multi carrier frequency division multiple access (MC-FDMA), etc.

Broadcast systems as well as the aforementioned communication systems have necessarily used a channel code. As a general method for configuring a channel code, a transmitting end can encode an input symbol using an encoder and transmitted the encoded symbol. In addition, for example, a receiving end can receive the encoded symbol and decode the received symbol to restore the input symbol. In this case, the size of the input symbol and the size of the encoded symbol can be defined in different ways according to a communication system. For example, in a turbo code for data information used in a long term evolution (LTE) communication system of a 3rd generation partnership project (3GPP), the size of the input symbol is a maximum of 6144 bits and the size of the encoded symbol is 18432 (6144*3) bites. Turbo coding in an LTE communication system may be referred to by the 3GPP technical standard 36.212.

However, the LTE turbo code has characteristics whereby enhancement in performance is slight when a signal to noise ratio (SNR) exceeds a predetermined range even if being increased due to a structure of the code. In this regard, a code with a low error rate as possible can be considered, but in this case, complexity is increased.

A high error rate in a communication system can cause retransmission of unnecessary data and failure in channel reception. In addition, a code with excessively high complexity can cause delay in transmission and reception as well as can increase loads of a base station and a user equipment (UE). In particular, a next-generation communication system that requires rapid transmission and reception of data as possible requires the aforementioned problems. Accordingly, there is a need for a coding method with a low error rate and low complexity.

In particular, current LTE turbo code has a problem in that error floor occurs when the amount of information is increased. Accordingly, there is a need for a channel coding method that satisfies an ultra-reliable radio (URR) and a low latency radio (LLR).

### SUMMARY OF THE INVENTION

Accordingly, the present invention is directed to a method of low-density parity check (LDPC) code encoding for reducing signal overhead and an apparatus therefor that substantially obviates one or more problems due to limitations and disadvantages of the related art.

An object of the present invention is to provide methods for replacing an existing long term evolution (LTE) turbo code with a low-density parity check (LDPC) code and reducing overhead of the LDPC code.

Another object of the present invention is to provide an apparatus for supporting these methods.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of low-density parity check (LDPC) code encoding includes generating a transport block (TB), attaching TB cyclic redundancy check (CRC) to the TB, segmenting the TB CRC-attached TB to generate a plurality of code blocks (CBs), determining whether to attach code block (CB) CRCs to corresponding CBs based on a channel state or a required error rate, encoding, when the CB CRCs are not attached, the plurality of CBs without the CB CRCs according to the LDPC code, and encoding, when the CB CRCs are attached, the plurality of CB CRCs-attached CBs according to the LDPC code.

The LDPC code encoding method may further include transmitting an indicator indicating whether the code block CRCs are attached, to a receiving end.

The LDPC code encoding method may further include inserting an additional reference signal into the plurality of code blocks when the code block CRCs are not attached.

The LDPC code encoding method may further include transmitting the plurality of encoded code blocks to a receiving end, and receiving feedback indicating failure in decoding of the transport block from the receiving end.

When the code block CRC is not attached, the feedback may contain an indicator indicating whether syndrome check for the plurality of code blocks is successful.

The indicator indicating whether the syndrome check is successful may contain information on a code block on which the syndrome check fails.

In another aspect of the present invention, a transmission terminal includes a transceiver configured to transmit and receive a signal, a memory, and a processor configured to control the transceiver and the memory, wherein the processor is configured to generate a transport block (TB), to attach TB cyclic redundancy check (CRC) to the TB, to segment the TB CRC-attached TB to generate a plurality of code blocks (CBs), to determine whether to attach code block (CB) CRCs to corresponding CBs based on a channel state or a required error rate, to encode, when the CB CRCs are not attached, the plurality of CBs without the CB CRCs according to a low-density parity check (LDPC) code, and to encode, when the CB CRCs are attached the plurality of CB CRCs-attached CBs according to the LDPC code.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a coding procedure according to an example;

FIG. 2 illustrates a procedure of encoding a transport block according to an example;

FIG. 3 illustrates a Recursive Systematic Convolutional (RSC) encoder according to an example;

FIG. 4 illustrates an LTE turbo encoder;

FIG. 5 illustrates an example of a trellis according to an RSC encoder;

FIG. 6 illustrates an example of a trellis structure;

FIG. 7 illustrates a structured parity check matrix according to an example;

FIG. 8 illustrates a model matrix according to an example;

FIG. 9 is a diagram for explanation of transformation of a matrix according to a shift number;

FIG. 10 is a flowchart illustrating an LDPC code decoding method according to a shift number;

FIG. 11 illustrates a bipartite graph according to a shift number;

FIG. 12 is a diagram illustrating an LDPC code encoding method according to an exemplary embodiment of the present invention; and

FIG. 13 is a diagram illustrating configuration of a base station and a user equipment according to an embodiment of the present invention.

### DETAILED DESCRIPTION OF THE INVENTION

The following technology may be used for various wireless access systems such as CDMA (code division multiple access), FDMA (frequency division multiple access), TDMA (time division multiple access), OFDMA (orthogonal frequency division multiple access), and SC-FDMA (single carrier frequency division multiple access). The CDMA may be implemented by radio technology such as universal terrestrial radio access (UTRA) or CDMA2000. The TDMA may be implemented by radio technology such as global system for mobile communications (GSM)/general packet radio service (GPRS)/enhanced data rates for GSM evolution (EDGE). The OFDMA may be implemented by radio technology such as IEEE 802.11 (Wi-Fi), IEEE 802.16 (WiMAX), IEEE 802.20, and evolved UTRA (E-UTRA). The UTRA is a part of the universal mobile telecommunications system (UMTS). A 3rd generation partnership project long term evolution (3GPP LTE) communication system is a part of an evolved UMTS (E-UMTS) that uses E-UTRA, and employs OFDMA on downlink while employing SC-FDMA on uplink. LTE-advanced (LTE-A) is an evolved version of the 3GPP LTE system.

For the sake of clarity, 3GPP LTE/LTE-A is mainly described, but the technical idea of the present invention is not limited thereto. Specific terms used for the embodiments of the present invention are provided to help the understanding of the present invention. These specific terms may be replaced with other terms within the scope and spirit of the present invention.

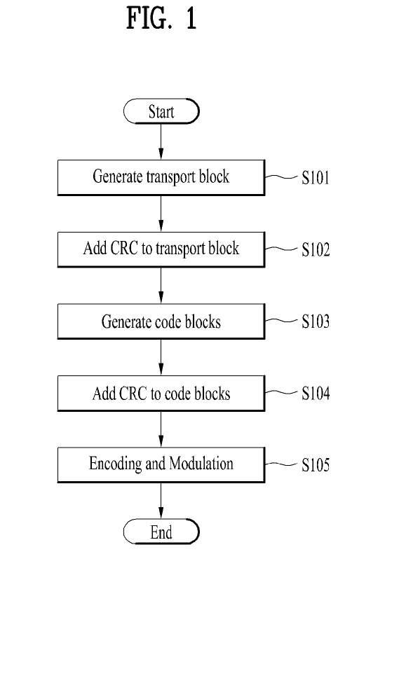

FIG. 1 illustrates a coding procedure according to an example.

The coding procedure as shown in FIG. 1 may be applied to many channel codes including a turbo code used in the LTE communication system. Hereinafter, for simplicity, the coding procedure will be described based on terminology according to LTE communication system standards.

In the example of FIG. 1, the transmitting end may generate a transport block (TB) (S101). In addition, the transmitting end adds a CRC bit for the transport block to the transport block (S102). In addition, the transmitting end may generate code blocks from the transport block to which the CRC bit is added (S103). For example, the transmitting end may segment the transport block into code blocks based on the input size of the encoder. Further, the transmitting end may add a CRC bit for each divided code block (S104). In this case, for example, the code block and the code block CRC bits may be configured with a size of 6144 bits. The transmitting end may perform encoding and modulation (S105) on each block including code blocks and CRC bits. For example, turbo coding may be applied as described above.

The decoding procedure may be performed in the reverse order of the coding procedure of FIG. 1. For example, the receiving end may decode each code block using a decoder corresponding to each encoder, finally construct one transport block, and then check whether the transport block has passed the CRC.

For example, the size of the input symbols may be different from that of the transport block (TB) from the Media Access Control (MAC) layer. If the size of the transport block is larger than the maximum input symbol size of the turbo code, the transport block may be segmented into a plurality of code blocks (CB). According to the LTE communication system standard, the size of the code blocks may be equal to a result obtained by subtracting the CRC (Cyclic Redundancy Check) bits from 6144 bits. An input symbol of a turbo code may be defined as data including code blocks and CRC or data including a transport block (wherein the size of the transport block is less than, for example, 6144 bits) and CRC. The size of the CRC bits is very small (e.g., a maximum of 24 bits) compared to 6144 bits. Accordingly, in the following description, unless otherwise defined, a code block may refer to the code block itself or a CRC bit corresponding to the code block, and a transport block refers to the transport block itself or CRC bits corresponding to the transport block.

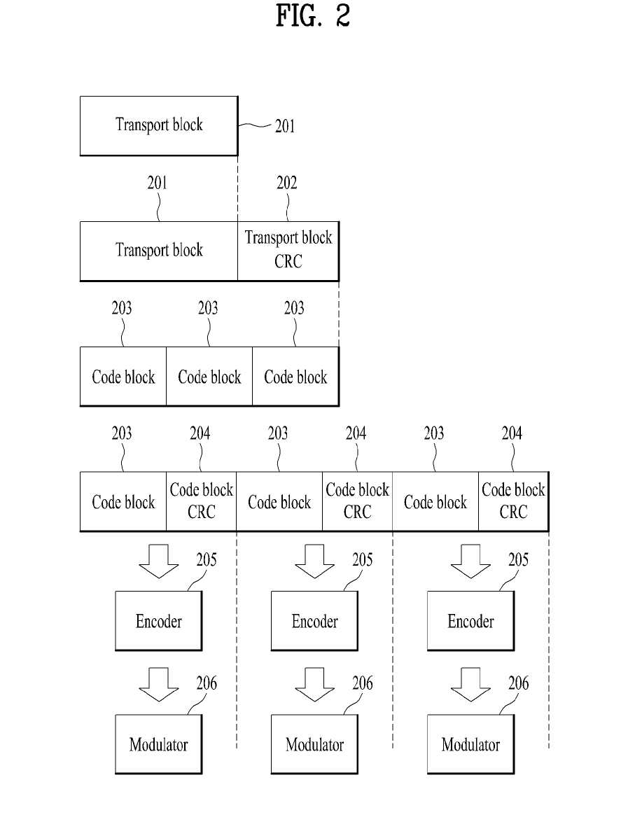

FIG. 2 illustrates a procedure of encoding a transport block according to an example.

FIG. 2 illustrates a procedure of encoding a transport block 201 corresponding to the coding procedure described above with reference to FIG. 1. First, transport block CRC 202 is added to the transport block 201. The transport block CRC 202 may be used for identification of the transport block 201 in the decoding procedure. The transport block 201 and the transport block CRC 202 are then segmented into three code blocks 203. While the transport block 201 is segmented into three code blocks 203 in this embodiment, the transport block 201 may be segmented into a plurality of code blocks based on the input size of the encoder 205.

Code block CRC 204 is added to each of the code blocks 203. The code block CRC 204 may be used for identification of the code block 203 at the receiving end. The code blocks 203 and the code block CRC 204 may be coded via the encoder 205 and the modulator 206.

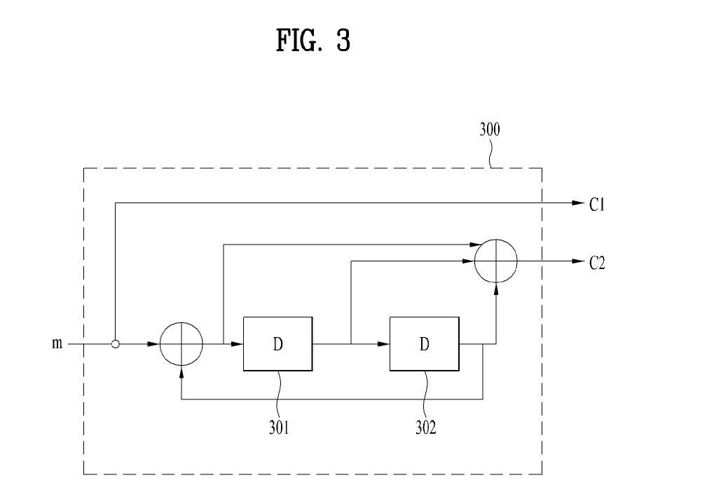

FIG. 3 illustrates a Recursive Systematic Convolutional (RSC) encoder according to an example.

An RSC encoder 300 of FIG. 3 may be used for turbo coding. In FIG. 3, m denotes input data, C1 denotes a systematic bit string, and C2 denotes a coded bit string. Here, the RSC encoder 300 has a code rate of ½.

The RSC encoder 300 may be configured by feeding back a coded output to the input of a nonrecursive nonsystematic convolutional encoder. In the embodiment of FIG. 3, the encoder 300 includes two delay units 301, 302. The value D of the delay units 301 and 302 may be determined according to a coding scheme. The delay unit 301, 302 may include a memory or a shift register.

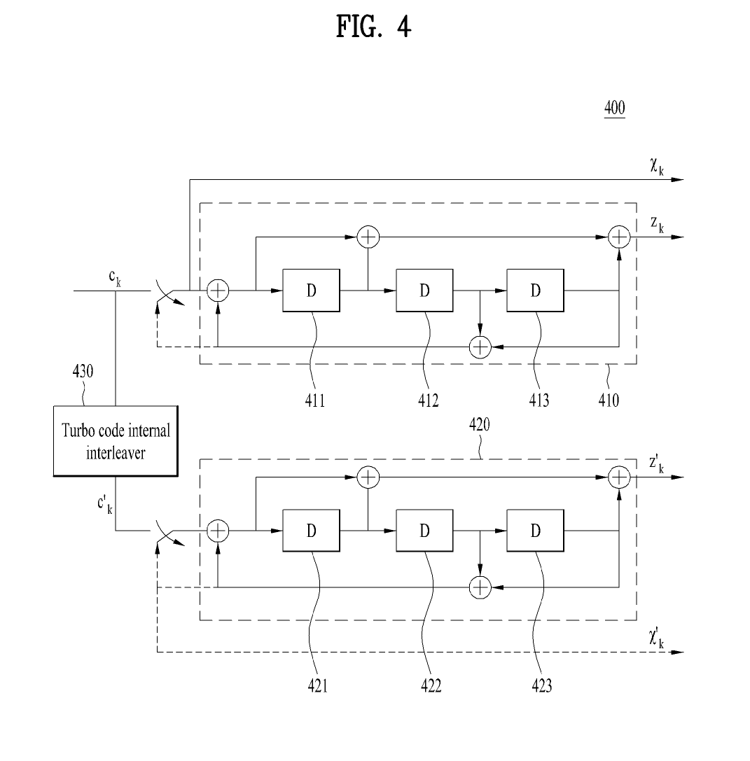

FIG. 4 illustrates an LTE turbo encoder.

The coding scheme of the LTE turbo encoder 400 is a parallel concatenated convolutional code (PCCC) having two 8-state constituent encoders 410 and 420 and a turbo code internal interleaver 430.

In FIG. 4, the turbo encoder 400 includes a first constituent encoder 410, a second element encoder 420, and a turbo code internal interleaver 430. The first constituent encoder 410 and the second constituent encoder 420 are 8-state constituent encoders. The first constituent encoder 410 and the second constituent encoder 420 are configured in a structure similar to that of the RSC encoder of FIG. 3. Each of the first constituent encoder 410 and the second constituent encoder 420 includes three delay units 411, 412 and 413, 421, 422 and 423.

In FIG. 4, D is a value determined according to a coding scheme anx cₖ is an input to the turbo encoder 400. The outputs from the first constituent encoder 410 and the second constituent encoder 420 are denoted by zₖ and z′ₖ, respectively. The value output from the turbo code internal interleaver 430 is denoted by c′ₖ. Generally, the delay units 411, 412, 413, 421, 422, 423 may delay the input values by one clock. However, the delay units 411, 412, 413, 421, 422, 423 may be configured to delay the input values by more than one clock depending on the internal configuration thereof. The delay unit 411, 412, 413, 421, 422, 423 may include a shift register, delay an input bit by a predetermined clock, and then output the input bit to the next delay unit 411, 412, 413, 421, 422, 423.

The turbo code internal interleaver 430 may lower the influence of a burst error that may occur when a signal is transmitted over a radio channel. For example, the turbo code internal interleaver 430 may be a quadratic polynomial permutation (QPP) interleaver.

The turbo code is a high performance forward error correction (FEC) code and is used in the LTE communication system. For example, a data block coded by the turbo code may include three sub-blocks. One of the sub-blocks may correspond to m-bit payload data. Another subblock may be configured with n/2 bits, i.e., parity bits for the payload, calculated using a recursive systematic convolution (RSC) code. The other subblock may be configured with n/2 bits, i.e., parity bits for permutation of payload data, calculated using an RSC code. For example, the above-described permutation may be performed by an interleaver. Thus, two sub-blocks having different parity bits and the payload may constitute one block. For example, if m is equal to n/2, one block has a code rate of ⅓.

In the first constituent encoder 410, the procedure in which the input cₖ reaches the coded bit zₖ may be divided into two paths. The two paths are a first path connected from an input terminal to an output terminal without output feedback and a second path fed back from an input terminal to the input terminal.

In the first path, an input cₖ passed through the delay unit 411, and an input cₖ passed through the delay units 411, 412, and 413 are applied to the output terminal. The relationship between the input terminal and the output terminal for the first path may be expressed by a polynomial. The polynomial for the first path is called a forward generator polynomial and may be expressed as g1 in the following equation.

g1(D)=1+D+D³ Equation 1

In the second path, an input cₖ, an input cₖ passed through the delay units 411 and 412, and an input cₖ passed through the delay units 411, 412 and 413 are fed back to the input terminal. The polynomial for the second path is called a recursive generator polynomial and may be expressed as g0 in the following equation.

g0(D)=1+D²+D³ Equation 2

In Equations 1 and 2, “+” means exclusive OR (XOR), and 1 means that the input undergoes 0 delay. In addition, Dⁿ means that the input undergoes n delays.

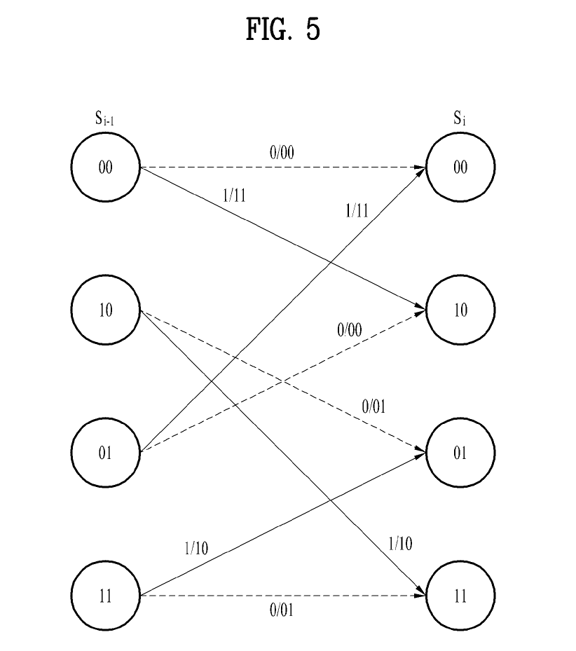

FIG. 5 illustrates an example of a trellis according to an RSC encoder.

FIG. 5 shows the structure of the trellis of the RSC encoder shown in FIG. 3. In FIG. 5, Sᵢ denotes the state of the i-th input data. In FIG. 5, each circle represents a corresponding node. In addition, a line connected between nodes represents a branch. The solid line represents a branch for the input value of 1, and the dotted line represents a branch for the input value of 0. The value on a branch is indicated by m/C1C2 (input value/systematic bit, coded bit). The trellis may also have a state that is exponentially proportional to the number of memories of the encoder. For example, if the number of memories included in the encoder is a, 2^{a} states may be included in the trellis.

The trellis is a state machine that shows a possible state transition of an encoder between two states. A convolutional encoder such as the RSC encoder may perform coding according to a trellis diagram. The codeword coded by the RSC encoder may be decoded according to an algorithm based on the trellis structure. For example, the Viterbi or BCJR (Bahl, Cocke, Jelinek and Raviv) algorithm may be used.

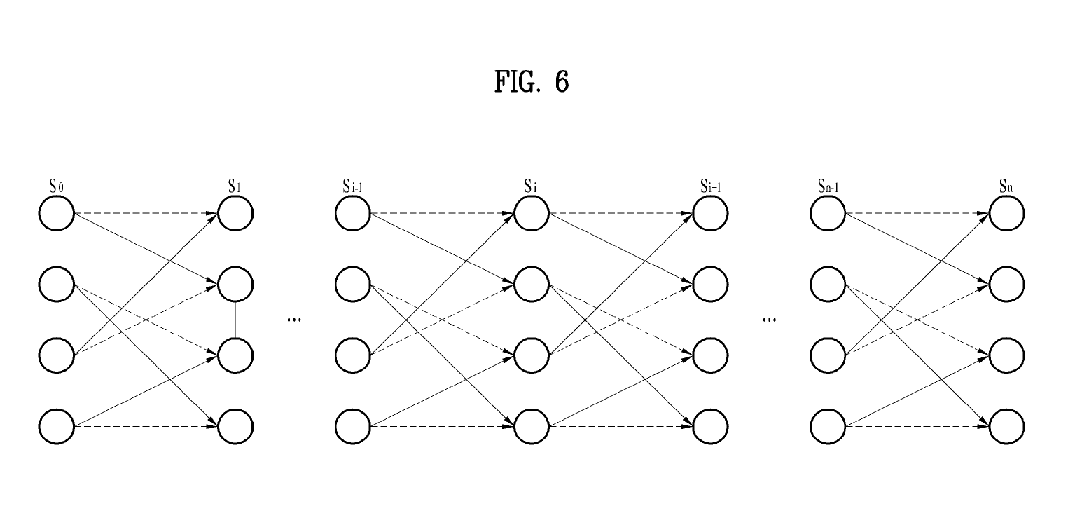

FIG. 6 illustrates an example of a trellis structure.

In FIG. 6, n denotes the length of a codeword. Typically, the trellis may be terminated by adding an additional bit after an input sequence. In general, a sequence configured as a sequence of 0 is referred to as a tail bit. The tail bit causes the nodes in one state of the trellis to have 0 as a value to terminate the trellis.

In FIG. 6, the length of the codeword may be determined in consideration of the length k of the input data and the length t of the tail bits. For example, if the code rate is R, the length n of the codeword may be (k+t)/R. In general, a length by which all delay units (e.g., memories) of the encoder may be reset may be determined as the length t of the tail bits. For example, the RSC encoder of FIG. 3 may use a total of 2 bits as the tail bits. The turbo encoder for LTE communication as shown in FIG. 4 may use 3 bits as the tail bits.

The length of the tail bits is shorter than the length of the input data. As described above, since the length of the codeword is associated with the length of the tail bits, loss of the code rate may occur due to the tail bits when the length of the codeword is limited. However, despite the loss of the code rate due to the tail bits, the trellis is terminated using the tail bits in many cases. This is because this method lowers computational complexity and exhibits excellent error correction performance.

The puncturing code refers to a method of puncturing a part of a codeword. In the puncturing code, a part of a codeword is punctured such that the part of the codeword is not transmitted. For example, the puncturing code may be used to lower the code rate loss caused by addition of tail bits. In this case, the receiving end may perform decoding using the trellis corresponding to the sum of the length k of the input data and the length t of the tail bits. That is, the receiving end may perform decoding on the assumption that the non-punctured codeword is received. In this case, the receiving end may consider that there is no input value for the branch from a node corresponding to the punctured bit (i.e., the bit not transmitted from the transmitting end). That is, for the branches of the node, the input data is assumed to be 0 or 1 with the same probability.

As described with reference to FIG. 1, CRC for a code block is added to a code block. The CRC may be determined as a remainder derived by dividing data that is a transmission target by a preset check value as a divisor. In general, the CRC may be added to an end of the transmission data. A receiving end may compare the remainder derived by dividing the data that is a transmission target by the preset check value with the CRC or determine whether the remainder obtained by dividing entire received data including the CRC by the check value is 0.

When a size of a transport block is 6144 bits, the size of the CRC may include a maximum of 24 bits. Accordingly, the remaining bits except for the CRC bits may be determined as a size of a code block.

The receiving end may perform decoding in a unit of each code block. Then, the receiving end may configure a transport block from the code block and check CRC for the transport block to determine whether decoding is successful. In a current LTE system, the code block CRC may be used for early decoding termination. For example, when CRC check with respect to one code block fails, the receiving end may transmit negative ACKnowledgement (NACK) to the transmission end without decoding the remaining code blocks.

Upon receiving the NACK, the transmission end may retransmit at least a portion of the transmission data. For example, the transmissions end may retransmit the transport block or one or more code blocks. For example, when all transport blocks are retransmitted, a radio resource may be excessively consumed for retransmission. For example, when NACK due to failure in code block CRC is generated in the receiving end, the receiving end may transmit information (e.g., index of code block) of the code block in which CRC failures occurs to the transmission end. In addition, the transmission end may transmit only the code block in which CRC failure occurs using the information of the code block so as to enhance radio resource efficiency. However, when the number of code blocks is increased, the amount of data for feedback of the code block information (e.g., index of code block) may be increased.

In an LTE communication system, the receiving end may notify the transmission end of whether data is successfully received using an ACK/NACK signal. In the ca se of a frequency division duplex (FDD), ACK/NACK for data received in an i^{th} subframe may be transmitted in an (i+4)^{th} subframe. When NACK is transmitted in an (i+4)^{th} subframe, retransmission may be performed in an (i+8)^{th} subframe. This is achieved by considering time for processing a transport block and time for generating ACK/NACK. This is because much time is taken for channel code processing for processing a transport block. In the case of time division duplex (TDD), ACK/NACK and a retransmission subframe may be determined based on time for processing a transport block and generating of ACK/NACK and uplink subframe allocation (e.g., TDD uplink/downlink configuration). In addition, ACK/NACK bundling and multiplexing may be used.

As described above, when a turbo code exceeds a predetermined SNR, more enhancement in an error rate is insignificant. As an alternative of the turbo code, a low-density parity check (LDPC) code has been proposed. The LDPC code is a linear block code and is used in IEEE 802.11n, 802.11ac, and digital video broadcasting (DVB). The LDPC code may include a generation matrix and a parity check matrix. In the LDPC code, data may be encoded via product of message bits and a generation matrix. In general, in the communication standard using the LDPC code, a parity check matrix may be used instead of the generation matrix. For example, data encoding may be performed using a parity check matrix.

The linear block code may be generated based on generation matrix G or parity check matrix H. According to the properties of the linear block code, the linear block code may be configured to satisfy Hc^{t} with respect to all codewords c. The LDPC code may also be executed by checking whether product of the parity check matrix H and the codeword c is ‘0’ like another linear block code. For example, whether the product (i.e., Hc^{t}) of a transposed matrix of the codeword c and the parity check matrix is 0 may be determined to perform decoding of the LDPC code.

With regard to an LDPC code, the parity check matrix may include most elements of 0 and the number of elements that are not 0 may be small compared with a code length. Accordingly, an LDPC code may be repeatedly decoded based on possibility. In an initially proposed LDPC code, the parity check matrix may be defined in the non-systematic form and a low weight is uniformly applied to rows and columns of the parity check matrix. The weight may refer to the number of 1 included in rows and columns.

As described above, the density of elements that are not 0 in the parity check matrix H of the LDPC code is low. Accordingly, the LDPC code has performance that is close to theoretical limitations of Shannon while having low decoding complexity. Due to the high error correction performance and low decoding complexity of the LDPC code, the LDPC code has properties appropriate for high-speed wireless communication.

Hereinafter, a structured LDPC code will be described.

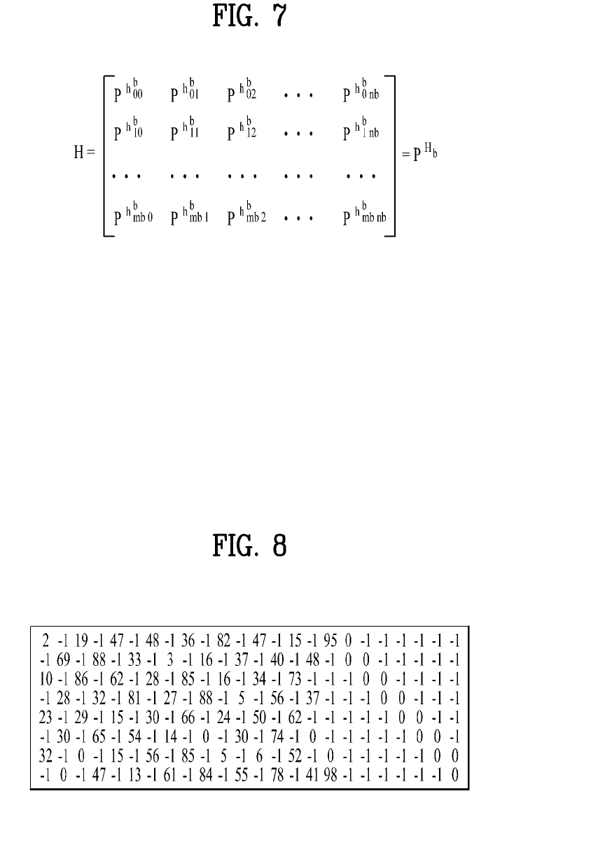

As described above, in order to generate an LDPC code, the parity check matrix H may be used. The matrix H may include a large number of elements 0 and a small number of elements 1. The matrix H may have a size of 10⁵ bits or more and a large portion of a memory may be consumed in order to represent the matrix H. In the structured LDPC code, elements of the matrix H may be represented as a predetermined size of sub-blocks, as illustrated in FIG. 7. In FIG. 7, each element of the matrix H may indicate one sub-block.

In the IEEE 802.16e standard document, a sub-block may indicate one integer index to reduce a size of a memory for representing the matrix H. Each sub-block may be, for example, a predetermined size of permutation matrix.

FIG. 8 illustrates a model matrix according to an exemplary embodiment of the present invention.

For example, with reference to the IEEE 802.16e standard document, when the size of a codeword is 2304 and a code rate is ⅔, a model matrix used for LDPC code encoding/decoding is illustrated in FIG. 8. The model matrix may refer to a parity check matrix including at least one sub-block that will be described below. A sub-block may be referred to as a shift number hereinafter. The model matrix may be extended to a parity check matrix based on a method that will be described below. Accordingly, encoding and decoding based on a specific model matrix may refer to encoding and decoding based on the parity check matrix generated from expanding of a corresponding model matrix.

In FIG. 8, index ‘−1’ indicates a predetermined size of zero matrix. In addition, index ‘0’ indicates a predetermined size of identity matrix. An index of a positive integer except for ‘−1’ and ‘0’ indicates a shift number. For example, a sub-block represented by index ‘1’ may refer to a matrix obtained by shifting an identity matrix one time in a specific direction.

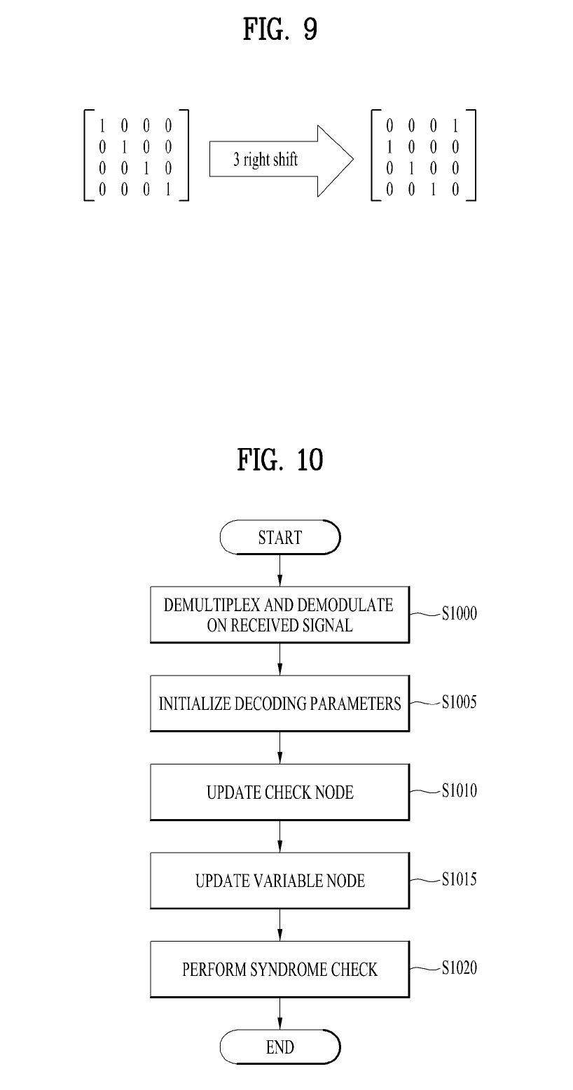

FIG. 9 is a diagram for explanation of transformation of a matrix according to a shift number.

For example, FIG. 9 illustrates the case in which a size of a sub-block has four rows and four columns. In FIG. 9, a sub-block is shifted three times in a right direction from the identity matrix. In this case, a parity check matrix of a code of a structured LDPC may represent a sub-block using an integer index of ‘3’.

In general, encoding of an LDPC code may be performed by generating a generation matrix G from the parity check matrix H and encoding an information bit using the generation matrix G. In order to generate the generation matrix G, Gaussian reduction may be performed on the parity check matrix H to configure a matrix in the form of [P^{T}:I]. When the number of information bits is k and a size of an encoded codeword is n, the matrix P refers to a matrix with k rows and (n-k) columns and I refers to an identity matrix.

When the parity check matrix H has the form of [P^{T}:I], the generation matrix G may have the form of [I:P^{T}]. When an information bit with a size of k bits is encoded, the encoded information bit may be represented in a matrix x with 1 row and k columns. In this case, a codeword c is xG and xG has the form of [x:xP]. Here, x indicates an information part (or systematic part) and xP indicates a parity part.

The matrix H may be designed as a special structure without Gaussian reduction so as to directly encode an information bit from the matrix H without inducing the matrix G. From the aforementioned structure of the matrix H and the matrix G, the product of the transposed matrices of the matrix G and the matrix H may have a value of 0. When these properties and a relationship between the aforementioned information bit and codeword are used, a parity bit may be added to an end of the information bit so as to acquire a codeword.

FIG. 10 is a flowchart illustrating an LDPC code decoding method according to an exemplary embodiment of the present invention.

In a communication system, encoded data may contain noise while passing through a radio channel. Accordingly, the codeword c may be represented as a codeword c′ containing noise at a receiving end. The receiving end may perform demultiplexing and demodulation on a received signal (S1000) and initialize decoding parameters (S1005). The receiving end may update a check node and a variable node (S1010 and S1015) and perform syndrome check (S1020). That is, c′H^{T} may be checked to be 0 to terminate a decoding procedure. When c′H^{T} is 0, first k bits may be determined as information bit x in c′. When c′H^{T} is not 0, c′ in which c′H^{T} satisfies 0 may be found based on a decoding scheme such as a sum-product algorithm to restore information bit x.

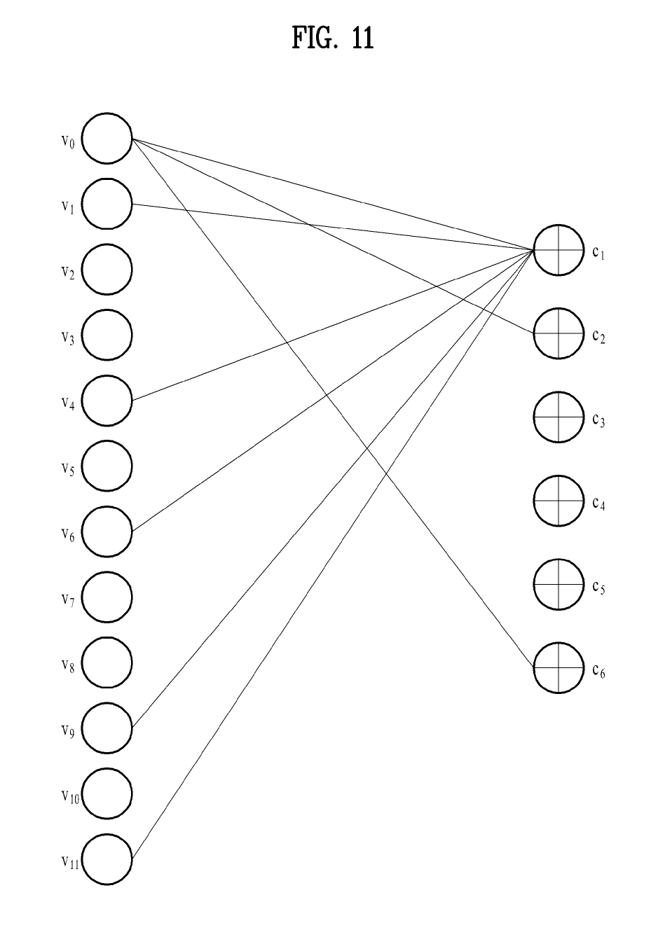

FIG. 11 illustrates a bipartite graph according to an exemplary embodiment of the present invention.

In FIG. 11, left nodes v₀, v₁, . . . , may indicate variable nodes and right nodes c₁, c₂, . . . , c₆ may indicate check nodes. In an example of FIG. 11, for convenience of description, the bipartite graph is illustrated based on variable node v₀ and check node c₁. Connection lines of the bipartite graph of FIG. 11 may be referred to as an edge. The bipartite graph of FIG. 11 may be generated from Hc^{t}. Accordingly, in FIG. 11, an edge of variable node v₀ may correspond to a first column of the parity check matrix H and an edge of check node c₁ may correspond to a first row of the matrix H.

As described above, for successful decoding, the product of the transposed matrices of the parity check matrix H and the codeword matrix c needs to be ‘0’. Accordingly, a value of variable nodes connected to one check node needs to be 0. Accordingly, in the case of FIG. 11, a value of exclusive OR (XOR) of a value of variable nodes v₀, v₁, v₄, v₆, v₉, and v₁₁ connected to the check node c₁ needs to be ‘0’. The syndrome check refers to checking whether a value of XOR of a value of variable nodes connected to each check node is 0.

An LDPC code in the IEEE 802.11n standard document may have a smaller maximum input data size and maximum codeword size than the LTE turbo code. Accordingly, compared with a turbo code, a large number of code blocks may be generated. As described above, a code block CRC is added to a code block and, thus, overhead due to CRC may be increased. Accordingly, a method of reducing overhead using syndrome check will be described below.

For example, syndrome check may be used instead of the code block CRC. The syndrome check has lower error detection possibility than CRC. Accordingly, even if error is not detected in syndrome check, error may occur in the transport block CRC check. On the other hand, when error is detected in syndrome check, error is inevitably detected in the transport block CRC check. Similarly, even if error is not detected from the code block CRC, error may be detected from the transport block CRC. However, the code block CRC and the transport block CRC use different polynomials and, thus, mismatch between the code block CRC and the transport block CRC may be reduced. Accordingly, the possibility of mismatch between the transport block CRC and the code block CRC may be lower than the possibility of mismatch between syndrome check and the transport block CRC. In particular, in an environment of high signal-to-noise ratio, when the code block CRC is used, a lower frame rate may be achieved than in the case in which syndrome check is used.

Accordingly, when syndrome check is used, low overhead may be obtained but low error correction performance may be obtained compared with the case in which the code block CRC is used. Accordingly, a channel coding chain may be determined based on gain and performance reduction due to overhead reduction. In particular, when a transmission environment is frequently changed (e.g., mm wave band sensitive to user motion), it is not easy to predict reception performance and, thus, sensitivity with respect to performance is not high. Accordingly, overhead may be reduced to reduce transmission power. In addition, overhead may be reduced and, thus, more reference signals may be inserted to rapidly estimate a channel.

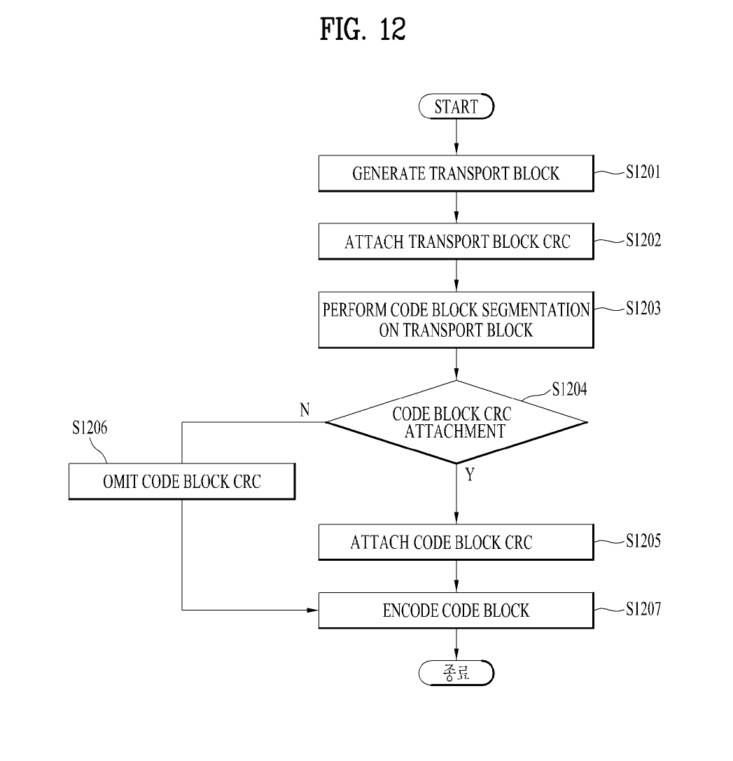

FIG. 12 is a diagram illustrating an LDPC code encoding method according to an exemplary embodiment of the present invention.

In FIG. 12, a transmission end may be, for example, an eNB. The transmission end may generate a transport block (S1201). The transmission end may attach a transport block CRC to the generated transport block (S1202). Then, the transmission end may perform code block segmentation on the transport block (S1203). The segmentation is performed for the transport block CRC attached transport block. According to a channel code, different sizes of code blocks may be used. Then, the transmission end may determine whether to attach a code block CRC to a code block (S1204).

For example, the transmission end may determine whether to attach the code block CRC based on a channel state and/or wireless communication system requirements. For example, the transmission end may determine whether the CRC is attached based on a required frame error rate (FER), block error rate (BLER), and/or modulation and coding scheme (MCS). For example, when FER, BLER and/or MCS is/are required more than predefined FER, BLER, and/or MCS, the transmission end may attach the code block CRC. For example, the transmission end may determine whether CRC is attached based on channel quality indicator (CQI) and/or other channel information that are reported from the receiving end or another UE. For example, the code block CRC may be omitted only when CQI with a preset value or more is reported. In addition, the transmission end may determine whether the CRC is attached based on transmission overhead. The transmission end may transmit information on whether the code block CRC is attached to the receiving end. For example, 1-bit indicator may be used. For example, information on whether the code block CRC is attached may be transmitted through physical downlink control channel (PDCCH), enhanced PDCCH (EPDCCH), or downlink control information (DCI). In addition, a reference signal may be inserted instead of the code block CRC. Information on the additional reference signal may also be transmitted to the receiving end through the aforementioned PDCCH, EPDCCH, or DCI.

The transmission end may attach the code block CRC (S1205) or may not attach the code block CRC (S1206) and then perform encoding on the code block (S1207). The transmission end may encode the code block based on the LDPC code. The encoding can be performed for the code block CRCs-attached code blocks or the code blocks without code block CRCs based on the determination of the step 5205. The transmission end may modulate the code block (S1208) and transmit the code block to the receiving end.

The receiving end (e.g., UE) may feedback a channel state and whether reception is successful to the transmission end based on a decoding result. For example, the receiving end may transmit a CQI index and/or acknowledgement/negative ACK (ACK/NACK). As described above, syndrome check may be used instead of the code block CRC. In this case, the receiving end may determine whether decoding is successful based on the transport block CRC and the syndrome check. In addition, when decoding fails, the receiving end may transmit information on whether the transport block CRC and the syndrome check fail to the transmission end. For example, the receiving end may transmit information on whether the syndrome check fails or the transport block CRC fails to the transmission end. As described above, when the syndrome check fails, the transport block CRC fails. However, even if syndrome check fails, the transport block CRC may be successful. Accordingly, when the syndrome check fails or the transport block CRC fails, the receiving end may transmit information on whether the syndrome check is successful to the transmission end. For example, a 1-bit indicator may be used. For example, an indicator of ‘0’ may indicate that the transport block CRC fails because the syndrome check fails. For example, an indicator of ‘1’ may indicate that the syndrome check is successful or the transport block CRC fails. For example, the receiving end may transmit information on whether the syndrome check and/or the transport block CRC fail to the transmission end using a physical uplink control channel (PUCCH) or uplink control channel (UCI).

For example, upon receiving information indicating that the syndrome check fails, the transmission end may use the code block CRC in retransmissions. For example, upon receiving information indicating that the syndrome check fails, the transmission end may determine MCS for a retransmission based on CQI, as like in a conventional LTE system. For example, upon receiving information indicating the syndrome check is successful and the transport block fails, the transmission end may determine MCS for retransmission based on the CQI or perform retransmission using the same MCS as a previous transmission. In the case of an LTE communication system, a performance difference between MCS indexes may be about 2 dB. However, a performance difference with code block CRC due to the syndrome check is about 0.04 dB and, thus, it may not be necessary to lower the MCS for retransmission.

In the case of LTE communication, etc., the code block CRC may be used for early termination of decoding. As described above, when the code block CRC fails, the UE may transmit information on the code block in which the code block CRC fails to the transmission end. Similarly, the syndrome check may be used for early termination of decoding. For example, when syndrome check fails, the receiving end may transmit information on a codeword in which the syndrome check fails to the transmission end. The transmission end may determine a codeword for retransmission based on the received information.

For example, CRC for a plurality of code blocks may be used instead of attaching the code block CRC to every code blocks. For example, similarly to an LTE communication system, CRC may be attached for every codeword. Similarly to a turbo code, LDPC code block CRC may be added every maximum of 6144 code block sizes. In this case, the transmission end may notify the receiving end of information on code block CRC attachment. For example, information on CRC may be transmitted through a 1-bit indictor. For example, attaching of the LDPC code block CRC every maximum of 6144 code block sizes may be set to default. In addition, an indicator with a value of ‘1’ may mean that the code block CRC is attached to every code blocks. For example, an n-bit (n is a natural number of 2 or more) indicator may be used. In this case, an interval for attaching the code block CRC may be indicated through an indicator. For example, a maximum interval for CRC attachment may be divided into parts and, then, the CRC attachment interval may be indicated by an indicator. The code block CRC may be attached only to some code blocks. In this case, the transmission end may indicate an index of a first code block to which the code block CRC is attached and an index of a last code block to the receiving end.

As described above, when a performance difference between the syndrome check and the code block CRC is little, the syndrome check may be used for overhead reduction. For example, in an LTE or enhanced mobile broadband (eMBB) communication environment with a target frame error rate (FER) of 10%, the syndrome check may be used instead of the code block CRC. In addition, in the case of ultra reliability & low latency communication (URLLC), the code block CRC may be attached to enhance performance.

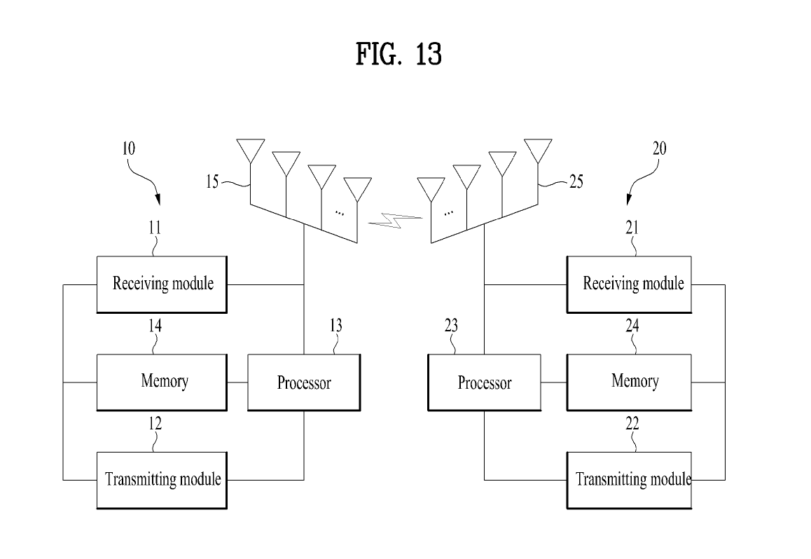

FIG. 13 is a schematic diagram for explanation of components of apparatuses to which the embodiments of the present invention of FIGS. 1 to 12 are applicable, according to an embodiment of the present invention.

Referring to FIG. 13, a BS apparatus 10 according to the present invention may include a receiving module 11, a transmitting module 12, a processor 13, a memory 14, and a plurality of antennas 15. The transmitting module 12 may transmit various signals, data, and information to an external apparatus (e.g., a UE). The receiving module 11 may receive various signals, data, and information from an external apparatus (e.g., a UE). The receiving module 11 and the transmitting module 12 may each be referred to as a transceiver. The processor 13 may control an overall operation of the BS apparatus 10. The antennas 15 may be configured according to, for example, 2-dimensional (2D) antenna arrangement.

The processor 13 of the BS apparatus 10 according to an embodiment of the present invention may be configured to receive channel state information according to proposed embodiments of the present invention. In addition, the processor 13 of the BS apparatus 10 may perform a function for calculating and processing information received by the BS apparatus 10 and information to be externally transmitted, and the memory 14 may store the calculated and processed information for a predetermined time period and may be replaced with a component such as a buffer (not shown) or the like.

Referring to FIG. 13, a UE apparatus 20 according to the present invention may include a receiving module 21, a transmitting module 22, a processor 23, a memory 24, and a plurality of antennas 25. The antennas 25 refer to a terminal apparatus for supporting MIMO transmission and reception. The transmitting module 22 may transmit various signals, data, and information to an external apparatus (e.g., an eNB). The receiving module 21 may receive various signals, data, and information from an external apparatus (e.g., an eNB). The receiving module 21 and the transmitting module 22 may each be referred to as a transceiver. The processor 23 may control an overall operation of the UE apparatus 20.

The processor 23 of the UE apparatus 20 according to an embodiment of the present invention may be configured to transmit channel state information according to proposed embodiments of the present invention. In addition, the processor 23 of the UE apparatus 20 may perform a function for calculating and processing information received by the UE apparatus 20 and information to be externally transmitted, and the memory 24 may store the calculated and processed information for a predetermined time period and may be replaced with a component such as a buffer (not shown) or the like.

The aforementioned components of the BS apparatus 10 and the UE apparatus 20 may be embodied by independently applying the above description of the present invention or simultaneously applying two or more embodiments of the present invention, and a repeated description is not given for clarity.

In addition, with regard to the various embodiments of the present invention, although an example in which a downlink transmission entity or an uplink reception entity is an eNB and a downlink reception entity or an uplink transmission entity is a UE has been described, the scope of the present invention is not limited thereto. For example, the above description of the eNB may be applied in the same way to the case in which a cell, an antenna port, an antenna port group, an RRH, a transmission point, a reception point, an access point, a relay, etc. are a downlink transmission entity to a UE or an uplink reception entity from the UE. In addition, the principle of the present invention that has been described with regard to the various embodiments of the present invention may also be applied in the same way to the case in which a relay is a downlink transmission entity to a UE or an uplink reception entity to a UE or the case in which a relay is an uplink transmission entity to an eNB or a downlink reception entity from an eNB.

The embodiments of the present invention may be achieved by various means, for example, hardware, firmware, software, or a combination thereof.

In a hardware configuration, an embodiment of the present invention may be achieved by one or more application specific integrated circuits (ASICs), digital signal processors (DSPs), digital signal processing devices (DSDPs), programmable logic devices (PLDs), field programmable gate arrays (FPGAs), processors, controllers, microcontrollers, microprocessors, etc.

In a firmware or software configuration, an embodiment of the present invention may be implemented in the form of a module, a procedure, a function, etc. Software code may be stored in a memory unit and executed by a processor. The memory unit is located at the interior or exterior of the processor and may transmit and receive data to and from the processor via various known means.

The embodiments of the present invention described above are combinations of elements and features of the present invention. The elements or features may be considered selective unless otherwise mentioned. Each element or feature may be practiced without being combined with other elements or features. Further, an embodiment of the present invention may be constructed by combining parts of the elements and/or features. Operation orders described in embodiments of the present invention may be rearranged. Some constructions of any one embodiment may be included in another embodiment and may be replaced with corresponding constructions of another embodiment. It is obvious to those skilled in the art that claims that are not explicitly cited in each other in the appended claims may be presented in combination as an embodiment of the present invention or included as a new claim by a subsequent amendment after the application is filed.

It will be apparent to those skilled in the art that various modifications and variations may be made in the present invention without departing from the spirit or scope of the inventions. Thus, it is intended that the present invention covers the modifications and variations of this invention provided they come within the scope of the appended claims and their equivalents.

According to the exemplary embodiments of the present invention, the following effects may be achieved.

The LDPC code encoding method according to the present invention may have low overhead compared with a conventional LDPC code.

The LDPC code encoding method according to the present invention may provide an adaptive encoding method to various communication environments selectively using code block CRC.

It will be appreciated by persons skilled in the art that that the effects that could be achieved with the present invention are not limited to what has been particularly described hereinabove and other advantages of the present invention will be more clearly understood from the detailed description taken in conjunction with the accompanying drawings.

The exemplary embodiments of the present invention may be applied various wireless access systems and broadcast communication systems. Examples of the various wireless access systems may include 3^{rd} generation partnership project (3GPP), 3GPP2, and/or institute of electrical and electronic engineers 802 (IEEE 802.xx) systems. Exemplary embodiments of the present invention may be applied any technological fields that applies the various wireless access systems as well as the various wireless access systems.

What is claimed is:

1. A method of low-density parity check (LDPC) code encoding of a transmission end, the method comprising:
generating a transport block (TB);
attaching TB cyclic redundancy check (CRC) to the TB;
segmenting the TB CRC-attached TB to generate a plurality of code blocks (CBs);
determining whether to attach code block (CB) CRCs to corresponding CBs based on a channel state or a required error rate;
encoding, when the CB CRCs are not attached, the plurality of CBs without the CB CRCs according to the LDPC code; and
encoding, when the CB CRCs are attached, the plurality of CB CRCs-attached CBs according to the LDPC code.

2. The method according to claim 1, further comprising transmitting an indicator indicating whether the CB CRCs are attached, to a receiving end.

3. The method according to claim 1, further comprising inserting an additional reference signal into the plurality of CBs when the CB CRCs are not attached.

4. The method according to claim 1, further comprising:
transmitting the plurality of encoded CBs to a receiving end; and
receiving feedback indicating failure in decoding of the TB from the receiving end.

5. The method according to claim 4, wherein, when the CB CRCs are not attached, the feedback contains an indicator indicating whether syndrome check for the plurality of CBs is successful.

6. The method according to claim 5, wherein the indicator indicating whether the syndrome check is successful contains information on a CB on which the syndrome check fails.

7. A transmission terminal of a wireless communication system, comprising:
a transceiver configured to transmit and receive a signal;
a memory; and
a processor configured to control the transceiver and the memory,
wherein the processor is configured to:
generate a transport block (TB),
to attach TB cyclic redundancy check (CRC) to the TB,
to segment the TB CRC-attached TB to generate a plurality of code blocks (CBs),
to determine whether to attach code block (CB) CRCs to corresponding CBs based on a channel state or a required error rate,
to encode, when the CB CRCs are not attached, the plurality of CBs without the CB CRCs according to a low-density parity check (LDPC) code, and
to encode, when the CB CRCs are attached the plurality of CB CRCs-attached CBs according to the LDPC code.

8. The transmission terminal according to claim 7, wherein the processor is further configured to transmit an indicator indicating whether the CB CRCs are attached, to a receiving end.

9. The transmission terminal according to claim 7, wherein the processor is further configured to insert an additional reference signal into the plurality of CBs when the CB CRCs are not attached.

10. The transmission terminal according to claim 7, wherein the processor is further configured to transmit the plurality of encoded CBs to a receiving end and to receive feedback indicating failure in decoding of the TB from the receiving end.

11. The transmission terminal according to claim 10, wherein, when the CB CRCs are not attached, the feedback contains an indicator indicating whether syndrome check for the plurality of code blocks is successful with.

12. The transmission terminal according to claim 11, wherein the indicator indicating whether the syndrome check is successful contains information on a CB on which the syndrome check fails.
